(19) United States
(12) Patent Application Publication
(10) Pub. No.: US 2012/0049205 A1
(43) Pub. Date: Mar. 1, 2012

(54) Structure of light-emitting diode (LED)

(75) Inventors: Huan-Ying Lu, Taipei Hsien (TW); Hung-Chih Lin, San Chung City (TW)

(73) Assignee: Unity Opto Technology Co., Ltd., Taipei Hsien (TW)

(21) Appl. No.: 12/923,047

(22) Filed: Aug. 31, 2010

(51) Int. Cl. H01L 33/00

(52) U.S. Cl. 257/88; 257/E33.056

(57) ABSTRACT

A stricture of light-emitting diode includes a substrate, a board, light-emitting dies, and packages. The board forms spaced reflection receptacles, each of which has a side wall forming an inclined reflection surface. The board has a surface on which conductive traces are formed. The light-emitting dies are respectively received in the reflection receptacles, and each light-emitting die is electrically connected to the conductive traces of the board. The packages are respectively set in the reflection receptacles of the board. In this arrangement, no insulation layer is required for the substrate, so that efficient heat dissipation can be realized, and thermal resistance can be reduced to thereby improve the operation performance of the light-emitting dies. Further, the inclined reflection surface of the reflection receptacles can be made even and consistent.

### FIELD OF THE INVENTION

The present invention relates to a structure of light-emitting diode (LED), and in particular to an LED structure that is formed of a combination of a substrate, a board, a plurality of light-emitting dies or chips, and a plurality of packages in order to make the LED structure applicable to various lighting devices.

### BACKGROUND OF THE INVENTION

A light-emitting diode (LED) has the characteristics of being small in size, low in power consumption, long in lifespan, and fast in response, making it perfectly complying with the current trend of environmental conservation. Many manufacturers are devoted themselves in the development and research of electronic devices that are related to or operated with LEDs. Thus, the application of LEDs is now expanded from wristwatches and calculators to lighting devices, automobiles, communications, computers, and traffic signals. Such an expansion rapidly increases the demand of LEDs. The conventional processes of manufacturing LEDs, however, are not sufficient to satisfy the current market demand for LEDs. One of the reasons is that a conventional LED structure requires machining a metal board that is combined with the light-emitting dies to form receptacles for the light-emitting dies through application of cutting tools to mill the metal board. Afterwards, subsequent operations of bonding an insulation layer and laying conductive traces are then carried out to form the conventional LED structure. However, it is hard to automatize such a conventional process of manufacturing LEDs. Further, the receptacle formed in the metal board through milling may show irregular surface evenness and inconsistency between surfaces of the receptacles.

Thus, the present invention aims to provide an LED structure that is formed of a combination of a substrate, a board, a plurality of light-emitting dies, and a plurality of packages and that comprises an insulator free heat dissipation arrangement so as to improve the convenience of use thereof.

### SUMMARY OF THE INVENTION

An objective of the present invention is to provide an LED structure that is formed of a combination of a substrate, a board, a plurality of light-emitting dies, and a plurality of packages and that comprises an insulator free heat dissipation arrangement.

To realize the above objective, the present invention provides a structure of light-emitting diode, which comprises a substrate; a board, which has a first surface bonded to a surface of the substrate and forms a plurality of spaced reflection receptacles, each of which has a side wall forming an inclined reflection surface, the board having a second surface on which conductive traces are formed; a plurality of light-emitting dies, which is respectively received in the reflection receptacles, each of the light-emitting dies being electrically connected to the conductive traces of the second surface of the board; and a plurality of packages, which is respectively set in the reflection receptacles and bonded to the light-emitting dies. As such, no insulation layer is required for the substrate, so that efficient heat dissipation can be realized, and thermal resistance can be reduced to thereby improve the operation performance of the light-emitting dies. Further, the present invention forms the reflection receptacles that have inclined reflection surface in the board by machining the board with milling tools so that, as compared to the conventional structure where receptacle are formed in a metal board, the inclined reflection surface of the reflection receptacles according the present invention show improved characteristics of evenness and consistency and also the lifespan of the milling tools can be extended.

### BRIEF DESCRIPTION OF THE DRAWINGS

The present invention will be apparent to those skilled in the art by reading the following description of preferred embodiments thereof with reference to the drawings, in which:

FIG. 1 is a schematic cross-sectional view illustrating a light-emitting diode (LED) structure according to a first embodiment of the present invention; and

FIG. 2 is a schematic cross-sectional view illustrating a light-emitting diode (LED) structure according to a second embodiment of the present invention.

### DETAILED DESCRIPTION OF THE PREFERRED EMBODIMENTS

### First Embodiment

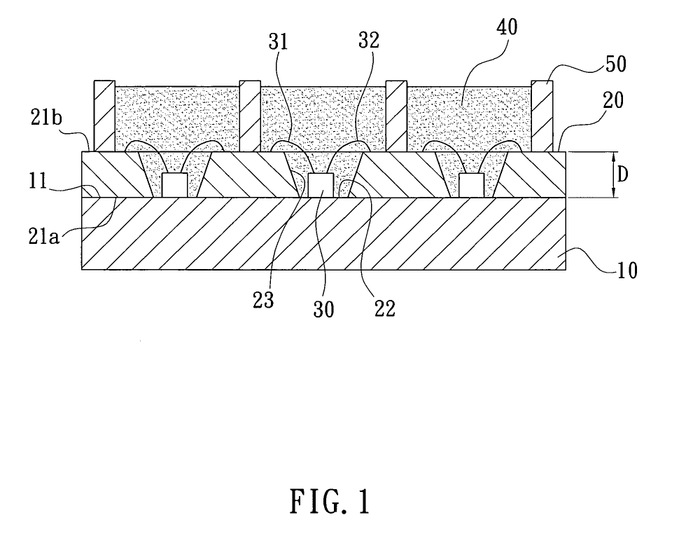

Referring to FIG. 1, which shows a schematic cross-sectional view of a structure of light-emitting diode (LED) according to a first embodiment of the present invention, the LED structure of the present invention comprises a substrate 10, a board 20 bonded to the substrate 10, a plurality of light-emitting dies 30 mounted on the board 20, and a plurality of packages 40 formed on the board 20 and respectively bonded to the light-emitting dies 30.

The board 20 has a surface 21a, which is bonded to a surface 11 of the substrate 10. The board 20 forms a plurality of reflection receptacles 22, which is spaced from each other. Each of reflection receptacles 22 is delimited by a side wall that forms an inclined reflection surface 23. The board 20 has an opposite surface 21b on which conductive traces (not shown) are formed.

The light-emitting dies 30 are set to correspond to and are respectively received and retained in the reflection receptacles 22.

The packages 40 are respectively set in the reflection receptacles 22 and bonded to the light-emitting dies 30.

In the embodiment illustrated, the substrate 10 is made of a metallic material and the board 20 is made of a non-metallic material, such as an epoxy glass fiber board or a plastic molded board. The board 20 has a thickness D, which is between 0.1 mm and 1 mm to provide an optimum result. The inclined reflection surface 23 of each of the reflection receptacles 22 of the board 20 may selectively coated with an electroplating layer to improve light emission efficiency.

Further, each of the light-emitting dies 30 comprises a first conductive wire 31 and a second conductive wire 32. The first conductive wire 31 and the second conductive wire 32 extend out of the reflection receptacle 22 and are electrically connected to the conductive traces formed on the surface 21b of the board 20. A baffle wall 50 is formed on the surface 21b of the board 20 adjacent to or surrounding a circumference of each of the reflection receptacles 22 in such a way that the inclined reflection surface 23 of the reflection receptacle 22 forms a stepped shoulder with respect to the baffle wall 50.

As such, through a combination of a substrate 10, a board 20, a plurality of light-emitting dies 30, and a plurality of packages 40, the present invention allows these components to be manufactured separately in a modularized manner thereby facilitating automatized mass production. Further, machining tools work on a non-metallic board 20 so that the life span of the machining tools can be extended.

Further, after the board 20 is bonded to the substrate 10, in order to make the inclined reflection surfaces 23 of the reflection receptacles 22 even and smooth, the inclined reflection surfaces 23 can be respectively coated with electroplating layers (not shown) to improve light emission efficiency. Further, the board 20 is bonded to the substrate 10 through pressing and conductive traces are formed on the board 20. As compared to the conventional structure of LED, the substrate 10 according to the present invention requires no formation of an insulation layer thereon so that the efficiency of heat dissipation is improved and the thermal resistance is reduced to thereby improve the performance of the light-emitting dies.

Further, the present invention forms baffle walls 50 formed on the surface 21b of the board 20 so that during a manufacturing process, spillage of packaging material out of the reflection receptacles 22 can be blocked by and bonded to the baffle wall 50 to form a tight enclosure.

### Second Embodiment

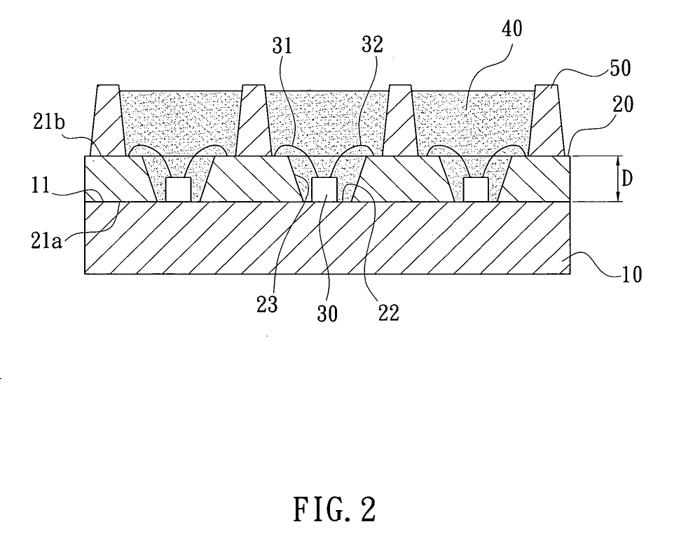

Referring to FIG. 2, which shows a schematic cross-sectional view of a structure of light-emitting diode according to a second embodiment of the present invention, as shown in the drawing, the structure of the second embodiment is different from that of the first embodiment in that the baffle walls 50 formed on the board 20 are of included wall surfaces, whereby the baffle walls 50, when combined with the inclined reflection surfaces 23 of the reflection receptacles 22, form a stepwisely convergent stepped arrangement. The light-emitting dies 30 can be electrically connected to the conductive traces of the board 20 through the first conductive wires 31 and the second conductive wires 32, or alternatively, the electrical connection is realized through flip-chip arrangement of the light-emitting die 30.

As such, with the inclined wall surfaces of the baffle walls 50, together with the inclined reflection surfaces 23 of the reflection receptacles 22, the board 20 according to the second embodiment may realize a double-layered effect of light reflection for each of the reflection receptacles 22, so as to improve the lighting effect of each light-emitting die 30.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A structure of light-emitting diode, comprising:
a substrate;
a board, which has a first surface bonded to a surface of the substrate and forms a plurality of spaced reflection receptacles, each of which has a side wall forming an inclined reflection surface, the board having a second surface on which conductive traces are formed;
a plurality of light-emitting dies, which is respectively received in the reflection receptacles, each of the light-emitting dies being electrically connected to the conductive traces of the second surface of the board; and
a plurality of packages, which is respectively set in the reflection receptacles and bonded to the light-emitting dies.

2. The structure of light-emitting diode as claimed in claim 1, wherein the substrate is made of a metallic material.

3. The structure of light-emitting diode as claimed in claim 1, wherein the board comprises one of epoxy glass fiber board and plastic molded board.

4. The structure of light-emitting diode as claimed in claim 1, wherein the board has a thickness between 0.1 mm and 1 mm.

5. The structure of light-emitting diode as claimed in claim 1, wherein the inclined reflection surfaces of the reflection receptacles are coated with an electroplating layer.

6. The structure of light-emitting diode as claimed in claim 1, wherein each of the light-emitting dies comprises a first conductive wire and a second conductive wire, which extend out of the reflection receptacle to electrically connect to the conductive traces of the second surface of the board.

7. The structure of light-emitting diode as claimed in claim 6, wherein the second surface of the board comprises a baffle wall formed thereon to surround a circumference of each of the reflection receptacles, the inclined reflection surface of the reflection receptacle forming a stepped shoulder with respect to the baffle wall.

8. The structure of light-emitting diode as claimed in claim 1, wherein the board comprises a baffle wall formed thereon to surround a circumference of each of the reflection receptacles, the inclined reflection surface of the reflection receptacle forming a stepped shoulder with respect to the baffle wall.

9. The structure of light-emitting diode as claimed in claim 7, wherein the baffle wall has an inclined wall surface.

10. The structure of light-emitting diode as claimed in claim 8, wherein the baffle wall has an inclined wall surface.
